(19) United States
(12) Patent Application Publication
(10) Pub. No.: US 2010/0200912 A1
(43) Pub. Date: Aug. 12, 2010

(54) Mosfets with terrace irench gate and improved source-body contact

(75) Inventor: Fu-Yuan Hsieh, Kaohsiung (TW)

Correspondence Address: BACON & THOMAS, PLLC, 625 SLATERS LANE, FOURTH FLOOR, ALEXANDRIA, VA, 22314-1176, US

(73) Assignee: FORCE MOS TECHNOLOGY CO. LTD., Kaohsiung (TW)

(21) Appl. No.: 12/379,012

(22) Filed: Feb. 11, 2009

(51) Int. Cl. H01L 29/78; H01L 21/336

(52) U.S. Cl. 257/329; 438/270; 257/E21.41; 257/E29.262

(57) ABSTRACT

A trench MOSFET with terrace gates and improved source-body contact structure is disclosed. When refilling the gate trenches, the deposited polysilicon layer is higher than the sidewalls of the trenches to be used as terrace gates of the MOSFET, and the improved source-body contact structure can enlarge the P+ area below to wrap the sidewalls and bottom of source-body contact within P body region to further enhance the avalanche capability.

### BACKGROUND OF THE INVENTION

1. Field of the Invention

This invention relates generally to the cell structure and fabrication process of power semiconductor devices. More particularly, this invention relates to a novel and improved cell structure and improved process for fabricating MOSFETs with terrace trench gate and improved source-body contact.

2. The Prior Arts

Please refer to FIG. 1 for a cell structure of MOSFET of prior art (U.S. Patent application No. 20080890357) with terrace gate structure for gate resistance reduction of shallow trench MOSFET. The MOSFET was formed on an N+ substrate 100 on which an N− doped epitaxial layer 102 was grown. Inside said epitaxial layer 102, a plurality of trenches were etched into the epitaxial layer 102 and lined with a layer of SiO₂ on the inner surface as gate dielectric material 108. To fill these trenches, doped poly was deposited not only within the trenches but also higher than the top surface of epitaxial layer 102 to form terrace gates 110 and at least one terrace gate 110′ for gate metal connection. Between each gate 110 and 110′, there was a P body region 112 introduced by Ion Implantation and N+ source regions 114 near the top surface of said P body area between gates 110. Said source regions and body regions were connected to source metal 120 via trench source-body contact 116 through a layer of thick oxide interlayer 118 while said terrace gate 110′ connected to gate metal 122 via trench gate contact 117. At the bottom of each trench source-body contact 116, an area of heavily P+ doped 106 was formed to reduce the resistance between source and body region.

Although the terrace gate structure were applied in the prior art to resolve the high gate resistance problem brought by typical recessed poly gate in shallow trenches for gate capacitance reduction, there are still some disadvantages constraining the performance of device and the implementation of fabricating process.

One disadvantage of the prior art is that, the trench of source-body contact 116 just barely penetrates through the N+ source region 114 with P+ region 106 only formation at the bottom of the contact trench. This structure will lead to a poor avalanche capability as the result of high contact resistance of source metal to P body region due to small P+ contact area. On the other hand, the resistance Rp underneath N+ source region between channel and P+ area is sufficiently high as there is no P implantation there. As is known to all, a parasitic N+/P/N will be turned on if Iav*Rp>0.7V where Iav is avalanche current originated from the gate trench bottom. Therefore, the structure of FIG. 1 has a poor avalanche capability which significantly affects the performance of whole device.

Another disadvantage of prior art is that, the source-body contact structure is not feasible for manufacturing because that the trench of source-body contact 116 may not penetrate through the N+ source region 114 and touch to P body region 112 across wafer or wafer to wafer or lot to lot due to uniformity tolerance requirement (±10% normally) of the contact trench etch. Thus a parasitic bipolar transistor will be turned on and the device will be then destroyed if the contact trench is not deep enough to touch P body.

Accordingly, it would be desirable to provide a trench MOSFET cell with improved source-body contact structure to avoid those problems mentioned above.

### SUMMARY OF THE INVENTION

It is therefore an object of the present invention to provide new and improved trench MOSFET cell and manufacture process to enhance the avalanche capability and to reduce the contact resistance.

One aspect of the present invention is that, as shown in FIG. 2, an improved self-aligned source-body contact structure is proposed, which has vertical contact trench sidewalls within thick oxide interlayer and N+ source region, and has slope contact trench sidewalls within P body region. Especially, inside said thick oxide interlayer, the trench width of top portion is larger than that of lower portion which because that, the CD (Critical Dimension) of said top portion is defined by trench mask while CD of said lower portion is defined by the concave area formed between two adjacent terrace gates, which accordingly leading to a good connection performance to the source metal deposited above. To be detailed, the contact trench sidewalls are substantially vertical (90±5 degree) within said thick oxide interlayer and N+ source region, and the taper angle is less than 85 degree respecting to the top surface of epitaxial layer within P body region, as illustrated in FIG. 4C. By employing this structure, the P+ area can be enlarged to wrapping the bottom and the slope sidewalls of source-body contact trench in P body region, which resolves the high Rp problem and enhances the avalanche capability.

Another aspect of the present invention is that, in another embodiment, as shown in FIG. 3, metal Al alloys or Cu is deposited onto top surface of device and into source-body contact trench over Ti/TiN or Co/TiN or Ta/TiN barrier layer to serve as both source metal and source-body contact material to further reduce fabrication cost and enhancing metal connection capability.

Briefly, in a preferred embodiment, as shown in FIG. 2, the present invention disclosed a trench MOSFET cell comprising: an N+ doped substrate with a layer of Ti/Ni/Ag on the rear side serving as drain metal; a lighter N doped epitaxial layer grown on said substrate; a plurality of trenches etched into said epitaxial layer as gate trenches; a first insulation layer serving as gate dielectric layer lining the inner surface of said gate trenches; doped polysilicon deposited higher than the top surface of epitaxial layer to form terrace gates; P body region extending between every two terrace gates; source regions near the top surface of P body regions; a second insulation layer as thick oxide interlayer deposited along the front surface of epitaxial layer and covering the outer surface of terrace gates above epitaxial layer; source-body contact trench penetrating through said second insulating layer and said N+ source region with vertical sidewalls while into P body region with slope sidewalls, and the trench width of top portion is larger; P+ area wrapping the slope sidewalls and bottom of source-body contact trench to enhance avalanche capability; tungsten metal refilled into said source-body contact trench acting as source-body contact metal over barrier layer of Ti/TiN or Co/TiN; metal Al alloys or Cu deposited onto a layer of Ti or Ti/TiN serving as source metal.

Briefly, in another preferred embodiment, as shown in FIG. 3, the trench MOSFET disclosed is similar to structure shown in FIG. 2 except that, metal Al alloys or Cu is deposited refilling the source-body contact and onto front surface of the second insulating layer over a Ti/TiN or Co/TiN or Ta/TiN barrier layer to serve as source-body contact material and source metal at the same time.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a side cross-sectional view of a trench MOSFET cell of prior art.

FIG. 2 is a side cross-sectional view of an embodiment for the present invention.

FIG. 3 is a side cross-sectional view of another embodiment for the present invention.

FIG. 4A to 4D are a serial of side cross sectional views for showing the processing steps for fabricating trench MOSFET cell in FIG. 2.

FIG. 5 is a side cross-sectional view to show the last process step for fabricating trench MOSFET cell in FIG. 3.

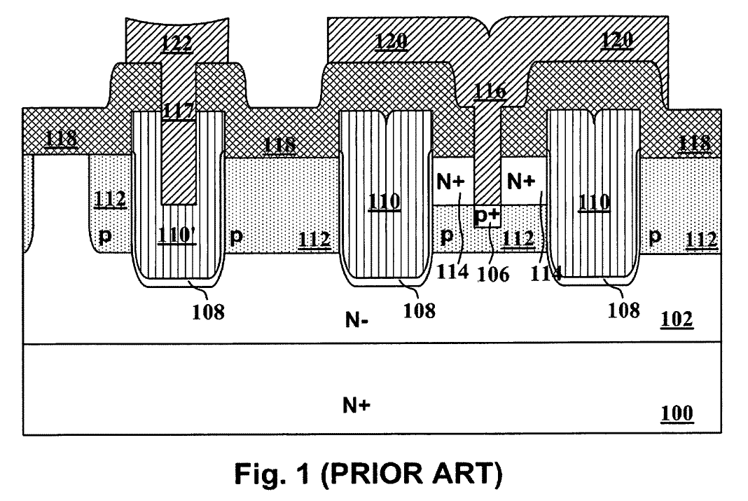

### DETAILED DESCRIPTION OF THE EMBODIMENTS

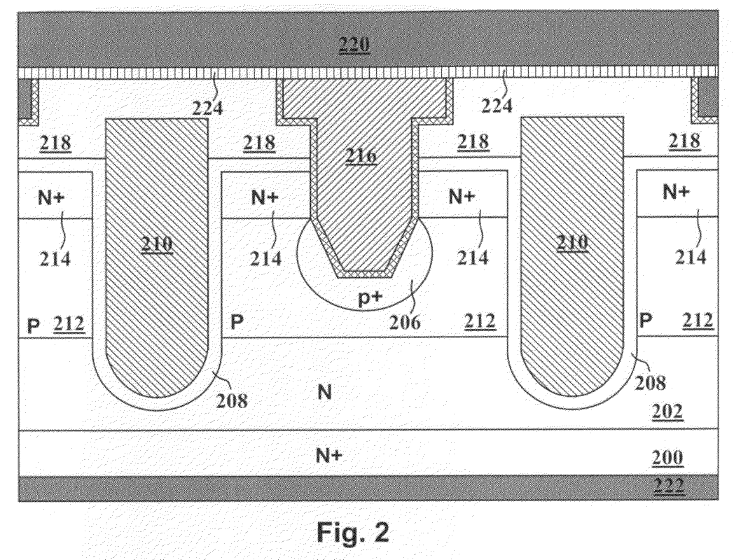

Please refer to FIG. 2 for a preferred embodiment of the present invention. The shown trench MOSFET cell is formed on an N+ substrate 200 coated with back metal Ti/Ni/Ag 222 on rear side as drain. Onto said substrate 200, grown an N− epitaxial layer 202, and a plurality of trenches were etched wherein. To fill these trenches, doped polysilicon was deposited not only within the trenches but also above the top surface of epitaxial layer to form terrace gates 210 over a first insulation layer 208 which serving as gate dielectric oxide. P body regions 212 are extending between terrace gates 210 with source regions 214 near the top surface of P body region. Source-body contact trench is etched through a second insulation layer 218, said N+ source region 214, and into said P body region 212. Especially, the sidewalls of source-body contact trench are perpendicular to the front surface of epitaxial layer within insulation layer and N+ source region 214 while is oblique within P-body region 212 with a taper angle less than 85 degree, meanwhile, inside said second insulation layer 218, the width of top portion of source-body contact trench is larger than lower portion. Underneath source-body contact metal plug 216 formed with W plug over Ti/TiN or Co/TiN or Ta/TiN barrier layer, a heavily P+ doped area 206 is formed wrapping the slope trench and the bottom in P-body region 212 to reduce the resistance between source and body and thus enhance the avalanche capability. Above thick second insulation layer 218, source metal 220 is deposited over a layer 224 of Ti or Ti/TiN to be electrically connected to source region 214 and body region 212 via source-body contact metal plug 216.

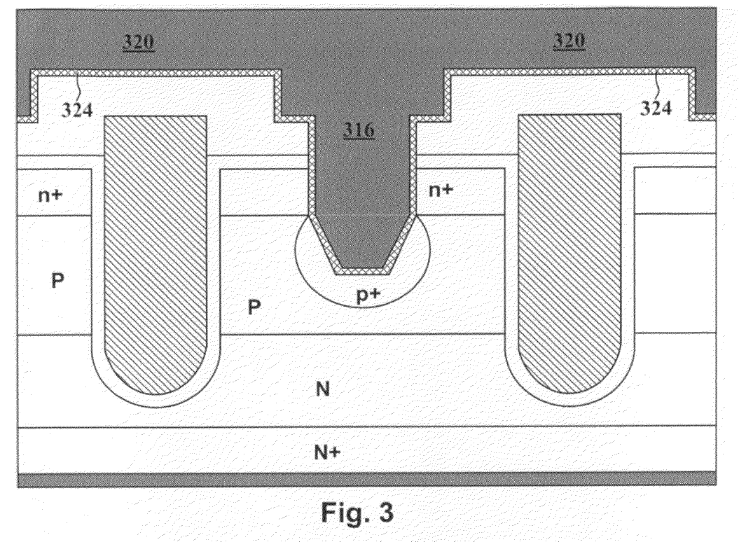

FIG. 3 shows another preferred embodiment of the present invention. Compared to FIG. 2, the source-body contact trench of FIG. 3 is filled with Al alloys or Copper over a barrier layer of Ti/TiN or Co/TiN or Ta/TiN to serve as source-body contact metal plug 316 and source metal 320 at the same time.

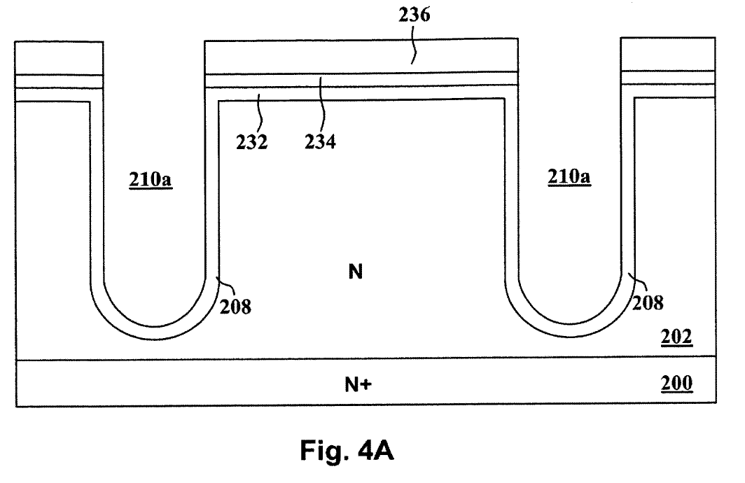

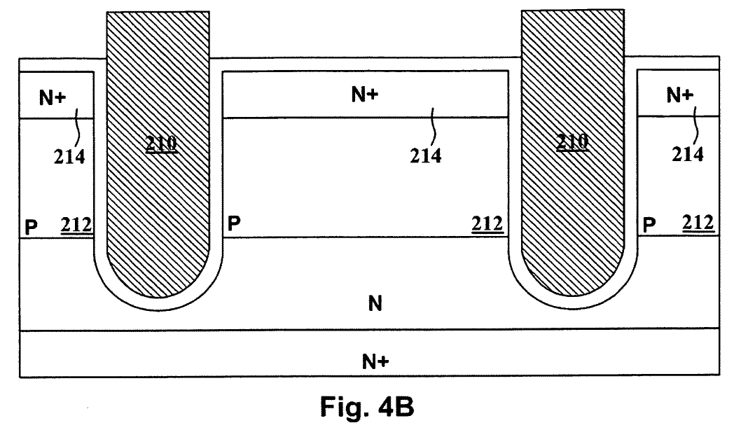

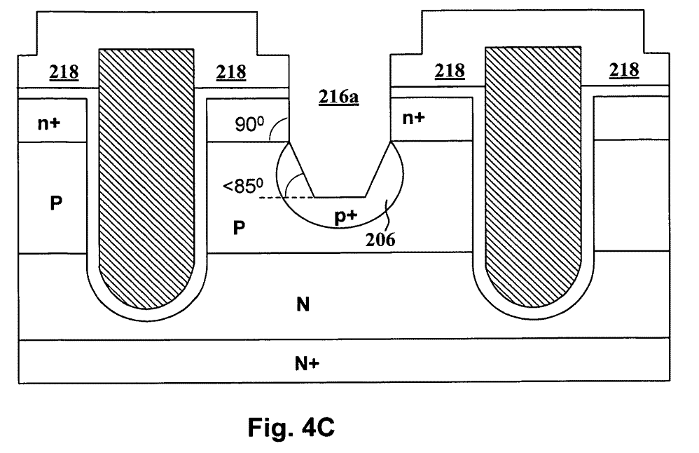

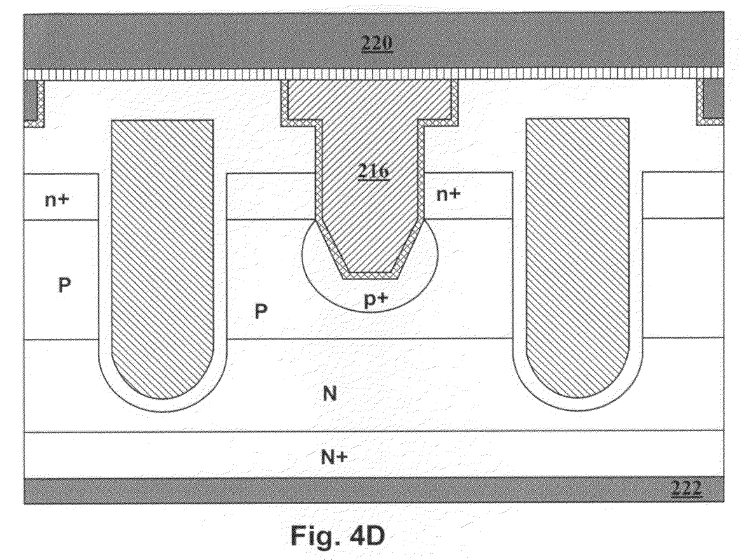

FIGS. 4A to 4D show a series of exemplary steps that are performed to form the inventive trench MOSFET of the present invention shown in FIG. 2. In FIG. 4A, a first semiconductor type epitaxial layer 202, which can be selected an N-type doped epitaxial layer is formed on a substrate 200, which is first semiconductor type silicon layer with higher first semiconductor type doping concentration and usually is indicated by N+ type. Thereafter, a thin layer of pad oxide 232 is grown with 100˜500 angstrom on the substrate 200. Then, a layer of SiN (Silicon Nitride) 234 is deposited about 1000˜2000 angstrom covering the whole structure and followed by the deposited of thicker oxide 236 which is about 4000˜8000 angstrom. After those three steps, a trench mask is applied to define the trenches 210a. Through a process of dry oxide/Nitride/oxide etching, trenches 210a are then dry silicon etched and followed with down-stream plasma silicon etch (remove about 100˜300 angstrom silicon) to remove the silicon defect along the trenches caused during the silicon trench etching process and round the trench bottom as well. Then, a sacrificial oxide layer is deposited and then removed (not shown) to remove plasma damage may introduced during opening gate trenches, and an oxide layer is grown or deposited along the sidewalls and the bottom of the each trench for a gate oxide 208 of the trench MOSFET.

In FIG. 4B, doped poly is deposited to refill all trenches, and then etched back either by CMP or dry poly etch to form a plurality of terrace gates which are extended upward the top surface of the oxide layer 236 (shown in FIG. 4A). Thereafter, the oxide layer 236 is etched by wet oxide etching, and the removal of SiN layer 234 (shown in FIG. 4A) is followed. Therefore, the terrace gate filled in the trenches 210a (shown in FIG. 4A) is defined as the terrace trench gates 210. Then, the process continues with second semiconductor type ion implantation and diffusion to form a plurality of body regions 212. After that, a first semiconductor type ion implantation and diffusion is carried out to form a plurality of source regions 214. In FIG. 4C, a thick layer of terrace oxide layer 218 is deposited as oxide interlayer to form at least one concave which is U-shape oxide structure above the mesa area between two adjacent terrace gates. Because the oxide interlayer 218 is almost uniformly grown along the outer surface of terrace gates 210, the concave is almost positioned at the middle portion between two adjacent terrace gates. Then, a source-body contact mask (not shown) is applied to carry out the top portion of source-body contact; next, the lower portion of said source-body contact is etched along the sidewalls of concave formed between two terrace gates by successive dry oxide etching and dry silicon etching. What should be noticed is that, the CD of source-body contact is larger than CD of U-shape concave between adjacent terrace gates. When etching through the oxide interlayer and N+ source region, sidewalls of source-body contact trench 216a are substantially vertical (90±5 degree) while etching into P body regions, sidewalls of source-body contact trench 216a has taper angle (less than 85 degree) respecting to top surface of epitaxial layer, as shown in FIG. 4C. Then, the BF2 Ion Implantation is carried out over entire surface to form P+ area 206 wrapping the sidewalls and bottom of source-body contact trench within P body region to further enhance avalanche capability, followed by a step of RTA (Rapid Thermal Annealing) to activate BF2.

In FIG. 4D, source-body contact trench 216a (shown in FIG. 4C) is filled with Ti/TiN/W or Co/TiN/W or Ta/TiN/W by a Ti/TiN/W or Co/TiN/W or Ta/TiN/W deposition. Then, W and Ti/TiN or Co/TiN or Ta/TiN etching back or CMP is performed to form source-body contact metal plug 216. After the deposition of Ti or Ti/TiN, metal layer of Al alloys or Cu is deposited on the front surface of device to serve as source metal 220, while metal Ti/Ni/Ag deposited on the rear side of wafer serving as drain metal 222.

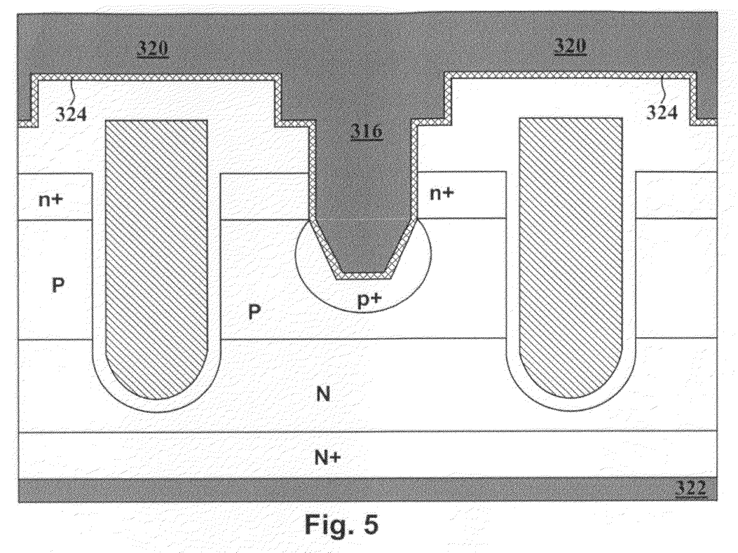

FIG. 5 shows the last step of forming structure in FIG. 3, after the same steps as shown in FIG. 4A to FIG. 4C, a barrier layer 324 of Ti/TiN or Co/TiN or Ta/TiN is deposited along the front surface of oxide interlayer and inner surface of source-body contact trench onto which Al alloys or Cu is deposited to form source-body contact metal plug 316 and source metal 320 by applying a metal mask. At last, a layer of Ti/Ni/Ag is deposited on the rear side of wafer to serve as drain metal 322.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A vertical semiconductor power MOS device comprising a plurality of semiconductor power cells with each cell comprising a plurality of trench gates surrounded by source regions encompassed in body regions above a drain region disposed on a bottom surface of a substrate, wherein said trench MOSFET further comprising:
a substrate of a first type conductivity;
an epitaxial layer of said first type conductivity over said substrate, having a lower doping concentration than said substrate;
a plurality of trenches extending into said epitaxial layer, surrounded by a plurality of source regions of said first type conductivity above said body regions of the second type conductivity;
a first insulation layer lining said trenches as gate dielectric;
a plurality of terrace gates made of doped polysilicon over said first insulation layer with top surface higher than front surface of said epitaxial layer;
a second insulation layer disposed over said epitaxial layer and covering the outer surface of said terrace gates to isolate source metal which contacts to said both source and body region, from said doped polysilicon as said terrace gate regions;
at least one source-body contact trench opened with sidewalls substantially perpendicular to a top epitaxial surface within source regions, and with tapered sidewalls respecting to said top surface into said body regions;
a heavily doped area of said second conductivity type around the sidewalls and bottom of said source-body contact trench within said body region;
a source-body contact metal plug deposited over a barrier layer to connect said source region and said body region to front source metal;
a front metal disposed on front surface of device as source metal;
a backside metal disposed on backside of said substrate as drain metal.

2. The trench MOSFET of claim 1, wherein the width of top portion of source-body contact is larger than lower portion within said second insulation layer;

3. The trench MOSFET of claim 1, wherein the angle between said source-body contact trench sidewalls and said top surface is 90±5 degree within said source regions and is less than 85 degree within said body region.

4. The trench MOSFET of claim 1, wherein said second insulation layer is SRO (Silicon Rich Oxide).

5. The trench MOSFET of claim 1, wherein said barrier layer is Ti/TiN or Co/TiN or Ta/TiN;

6. The trench MOSFET of claim 1, wherein said source-body contact trenches are filled with W metal or Al alloys or Cu.

7. The trench MOSFET of claim 1, wherein said front source metal is Al alloys or Cu overlying barrier layer of Ti/TiN or Co/TiN or Ta/TiN which covers the surface of said second insulation layer and fills said source-body contact trench when said source-body contact trench is filled with same material as front source metal.

8. The trench MOSFET of claim 1, wherein said front source metal is Al alloys or Cu overlying a layer of Ti or Ti/TiN which covering the front surface of said second insulation layer and said W metal plug when said source-body contact trench is filled with W metal.

9. The trench MOSFET of claim 1, wherein said drain metal is Ti/Ni/Ag.

10. A method for manufacturing a trench MOSFET with terrace gate and improved source-body contact comprising the steps of:
growing epitaxial layer on a heavily doped substrate;
forming a thin pad layer followed with deposition of a silicon nitride and a thick oxide layer;
applying a trench mask to open a plurality of gate trenches into the epitaxial layer;
following with down-stream plasma silicon etch;
growing and removing a sacrificial oxide;
forming a gate oxide and depositing a doped polysilicon layer;
removing the doped polysilicon layer from surface of thick oxide layer and leave the doped polysilicon in gate trenches;
removing the thick oxide layer and silicon nitride layer;
forming body regions by ion implantation into the epitaxial layer followed by diffusion;
forming source regions by ion implantation near the top surface of body regions followed by diffusion;
depositing an oxide interlayer to define a concave area;
applying a contact mask with contact opening larger than the concave area and etching said terrace oxide interlayer with CD defined by contact mask to a certain depth;
opening the source-body contact hole by dry oxide etching and dry silicon etching into P body region with CD defined by said concave area;
implanting BF2 ion through said source-body contact trench with the same type dopant as the body region around the sidewalls and bottoms of said source-body contact trench within P body region followed by a step of RTA to activate BF2 ion;
depositing barrier layer of Ti/TiN or Co/TiN or Ta/TiN lining inner surface of source-body contact or lining inner surface of source-body contact and onto front surface of terrace oxide interlayer;
depositing W metal refilling into source-body contact and remove it from top surface of the oxide interlayer, then followed by deposition of Ti or Ti/N and Al alloys or Cu successively or depositing Al alloys or Cu refilling into source-body contact covering barrier layer as source-body contact plug and source metal as well;
depositing a layer of Ti/Ni/Ag on the rear side of wafer as drain metal.

11. The method of claim 9, wherein said pad oxide is about 100˜500 angstrom.

12. The method of claim 9, wherein said Silicon Nitride is about 1000˜2000 angstrom.

13. The method of claim 9, wherein said thick oxide is about 4000˜8000 angstrom.
